(19) United States
(12) Patent Application Publication
(10) Pub. No.: US 2026/0136945 A1
(43) Pub. Date: May 14, 2026

(54) OVERLAY MARK, METHOD OF FORMING SAME AND MEASUREMENT METHOD

(71) Applicant: Hangzhou HFC Semiconductor Co., Hangzhou (CN)

(72) Inventors: Bin WEI, Hangzhou (CN); Yeli ZHANG, Hangzhou (CN)

(21) Appl. No.: 19/019,678

(22) Filed: Jan. 14, 2025

(30) Foreign Application Priority Data
Nov. 12, 2024 (CN) 202411604225.8

(51) Int. Cl. H01L 23/544

(52) U.S. Cl. CPC H10W 46/00; H10W 46/301

(57) ABSTRACT

An overlay mark, a method of forming the overlay mark and a measurement method are disclosed. The overlay mark includes a main mark and at least one assist pattern. The main mark includes a previous-layer mark and a current-layer mark. The current-layer mark is arranged within a contour of the previous-layer mark, and the previous-layer mark is arranged on the internal side of the assist pattern. The assist pattern may be formed in a current photoresist layer at a corresponding location outside the previous-layer mark to isolate or block out the photoresist layer at the current-layer mark, thereby avoiding the current-layer mark from being affected by patterns surrounding the overlay pattern, increasing overall accuracy of overlay error measurement data.

### CROSS-REFERENCE TO RELATED APPLICATION

This application claims the priority of Chinese patent application number 202411604225.8, filed on Nov. 12, 2024 and entitled “OVERLAY MARK, METHOD OF FORMING SAME AND MEASUREMENT METHOD”, the entire contents of which are incorporated herein by reference.

### TECHNICAL FIELD

The present invention relates to semiconductor photolithography and, in particular, to an overlay mark, a method of forming the overlay mark and a measurement method.

### BACKGROUND

Photolithography is a process involving a sequence of steps including alignment and exposure for transferring a reticle pattern onto a wafer. Semiconductor device fabrication may involve multiple photolithography overlay processes each involving measuring relative positions of patterns formed in the current and previous layers of a wafer with a dedicated device and then determining an overlay (OVL) error by processing images using an algorithm. The overlay error quantitatively describes deviations between the patterns in the current and previous layers in the X and Y directions and how these deviations are distributed across the wafer surface. It is a key indicator for production and relates to the yield of products. Mark currently used in the art for overlay error measurement can be principally categorized into two classes: imaging-based overlay (IBO) and diffraction-based overlay (DBO).

Common IBO mark includes Bar-in-Bar, Box-in-Bar and Box-in-Box marks. FIGS. 1 to 3 show examples of such marks formed in previous 200 and current 100 layers. Use of these IBO mark for overlay error measurement is, however, associated with the problem of a poor profile or distortion of photoresist for the current layer, as shown in FIGS. 6 to 9. This may lead to inaccurate signals read from the mark and hence inaccurate overlay error measurement data.

It should be noted that the information disclosed in this Background section is merely intended to provide a better understanding of the general context of the present invention and should not be taken as an acknowledgement or any form of admission that the information forms part of the common general knowledge of those skilled in the art.

### SUMMARY OF THE INVENTION

It is an object of the present invention to provide an overlay mark, a method of forming the overlay mark and a measurement method, which overcome the problem of significant deviations in overlay error measurement data that may occur when thick photoresist is used.

To this end, the present invention provides a method of forming an overlay mark comprising main mark and at least one assist pattern. The main mark includes a previous-layer mark and a current-layer mark. The current-layer mark is arranged within a contour of the previous-layer mark, and the previous-layer mark is arranged on an internal side of the assist pattern. The method comprises:
applying a photoresist layer to a substrate with the previous-layer mark being formed therein; and
forming the current-layer mark and the assist pattern by exposing and developing the photoresist layer, and removing a portion of the photoresist at the assist pattern, thereby isolating the photoresist at the current-layer mark.

On the basis of the same inventive concept, there is also disclosed herein an overlay mark formed according to the method as defined above. The overlay target comprises:
a previous-layer mark arranged in a previous dielectric layer of a substrate, the previous-layer mark comprising an internal side and an external side opposite to the internal side;
a current-layer mark formed in a current dielectric layer on the internal side of the previous-layer mark; and
at least one assist pattern formed in the current dielectric layer at a corresponding location on the external side of the previous-layer mark, the assist pattern spaced apart from the previous-layer mark at a predetermined distance.

On the basis of the same inventive concept, there is also disclosed herein an overlay error measurement method that is used to measure an overlay error of the overlay mark of claim 8.

In the formation method of the present invention, a novel overlay mark is formed, which additionally includes an assist pattern in a current photoresist layer at a corresponding location outside a previous-layer mark. The assist pattern isolates or blocks out the photoresist layer at a current-layer mark, avoiding it from being affected by patterns surrounding the overlay mark. In this way, when this IBO overlay target is used in thick photoresist applications, the current-layer mark is more resistant to deformation, increasing overall accuracy of overlay error measurement data so that the overall overlay error measurement data reflects a true photolithography overlay error.

The overlay mark of the present invention is based on the same inventive concept as the formation method and therefore provides at least all the advantages thereof, and thus further description is omitted.

The overlay error measurement method of the present invention is based on the same inventive concept as the overlay mark and therefore provides at least all the advantages thereof, and thus further description is omitted.

### BRIEF DESCRIPTION OF THE DRAWINGS

Those of ordinary skill in the art would appreciate that the following drawings are presented to enable a better understanding of the present invention and do not limit the scope thereof in any sense, in which:

FIG. 1 shows a schematic structural view of an existing Bar-in-Bar mark;

FIG. 2 shows a schematic structural view of an existing Box-in-Bar mark;

FIG. 3 shows a schematic structural view of an existing Box-in-Box mark;

FIG. 4 shows raw data of existing overlay marks in different surrounding patterns;

FIG. 5 shows Qmerit data of existing overlay marks in different surrounding patterns;

FIG. 6 shows an electron microscopy image of an existing mark;

FIG. 7 shows another electron microscopy image of the existing mark;

FIG. 8 shows yet another electron microscopy image of the existing mark;

FIG. 9 shows a schematic cross-sectional view taken along A-B of FIG. 1;

FIG. 10 shows a schematic structural view of a Bar-in-Bar mark according to an embodiment of the present invention;

FIG. 11 shows a schematic structural view of a Box-in-Bar mark according to an embodiment of the present invention;

FIG. 12 shows a schematic structural view of a Box-in-Box mark according to an embodiment of the present invention;

FIG. 13 shows a schematic structural view of a Bar-in-Bar mark according to an embodiment of the present invention;

FIG. 14 shows a schematic structural view of a Box-in-Bar mark according to an embodiment of the present invention;

FIG. 15 shows a schematic structural view of a Box-in-Box mark according to an embodiment of the present invention; and

FIG. 16 shows a schematic cross-sectional view taken along C-D of FIG. 10.

### LIST OF REFERENCE NUMERALS

100 current-layer mark; 200 previous-layer mark; 300 assist pattern.

### DETAILED DESCRIPTION

Objects, features and advantages of the present invention will become more apparent upon reading the following detailed description of specific embodiments thereof in conjunction with the accompanying drawings. Note that the figures are provided in a very simplified form not necessarily drawn to exact scale for the only purpose of helping explain the disclosed embodiments in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents, and the term “or” is generally employed in the sense of “and/or”, “a number of” is generally employed in the sense of “at least one” and “at least two” is generally employed in the sense of “two or more”. Additionally, the use of the terms “first”, “second” and “third” herein is intended for illustration only and is not to be construed as denoting or implying relative importance or as implicitly indicating the numerical number of the referenced items. Accordingly, defining an item with “first”, “second” or “third” is an explicit or implicit indication of the presence of one or at least two of such items. The terms “one end” and “other end”, as well as “proximal end” and “distal end”, may be used herein to generally refer to corresponding end portions including corresponding endpoints, rather than only to the endpoints. As used herein, the terms “mounting”, “coupling” and “connecting” and any variants thereof should be interpreted in a broad sense. For example, a connection may be a permanent, detachable or integral connection, or a mechanical or electrical connection, or a direct or indirect connection with one or more intervening media, or an internal communication or interaction between two components. Further, when an element is referred to herein as being “disposed” on another element, this is generally intended to only mean that there is a connection, coupling, engagement or transmission relationship between the two elements, which may be either direct or indirect with one or more intervening elements, and should not be interpreted as indicating or implying a particular spatial position relationship between them. That is, the element may be located inside, outside, above, under, beside, or at any other location relative to the other element, unless the context clearly dictates otherwise. Those of ordinary skill in the art can understand the specific meanings of the above-mentioned terms herein, depending on their context.

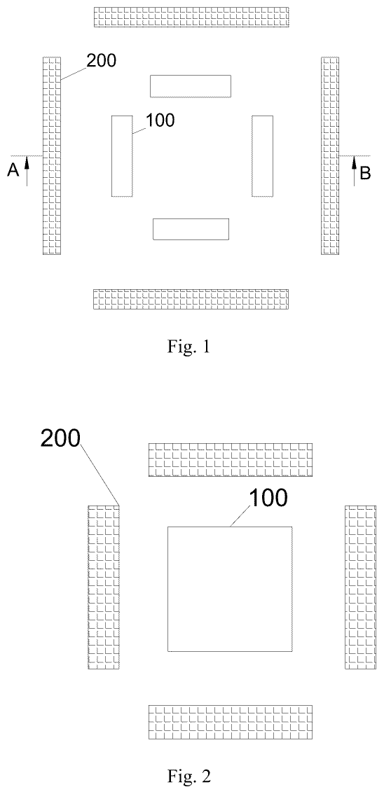

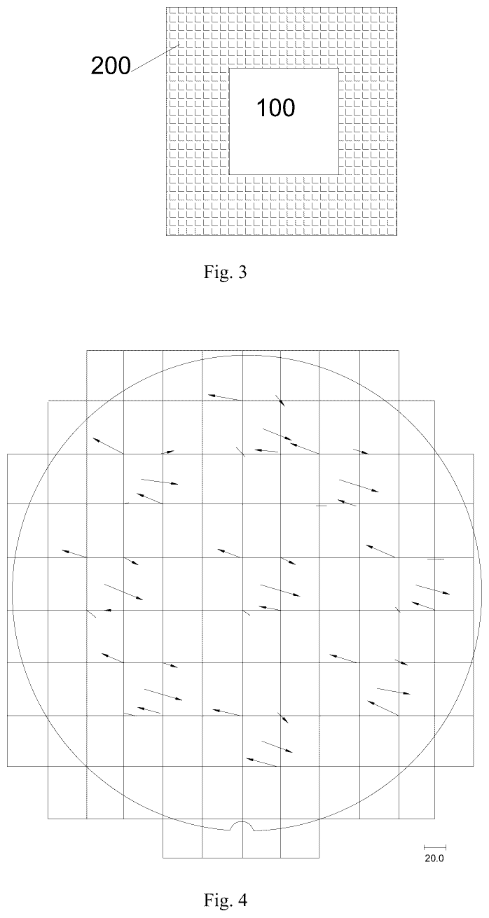

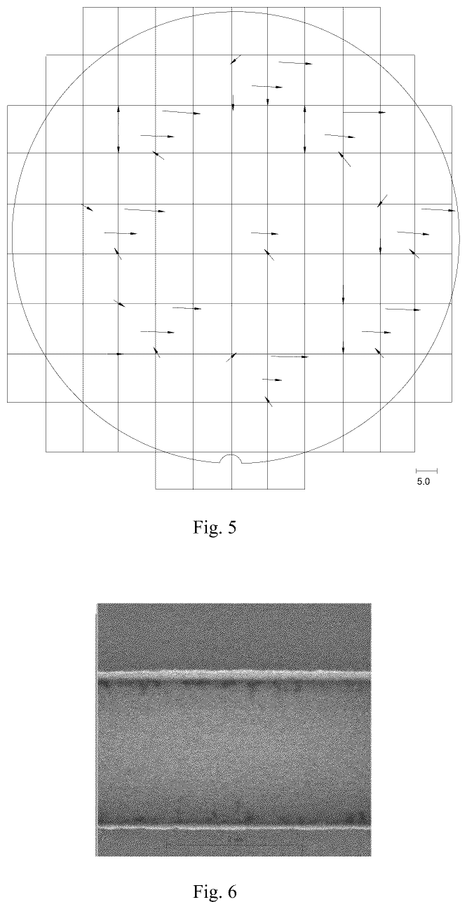

Through extensive research, the inventors have found that most conventional overlay marks are Bar-in-Bar, Box-in-Bar and Box-in-Box marks as shown in FIGS. 1 to 3. Raw data analysis and Qmerit data analysis of such overlay marks in different surrounding patterns, as shown in FIGS. 4 to 5, reveal that Raw data diverges in two directions and Qmerit data shows considerable differences of the center and the upper right corner from the rest. This is considered attributable to asymmetric photoresist (PR) around the overlay marks, which may be in turn caused by non-uniform PR application during a post apply bake (PAB) process. Different PR sizes may lead to PR curing and shrinkage at different rates, introducing asymmetry to the overlay marks and deteriorating Qmerit data.

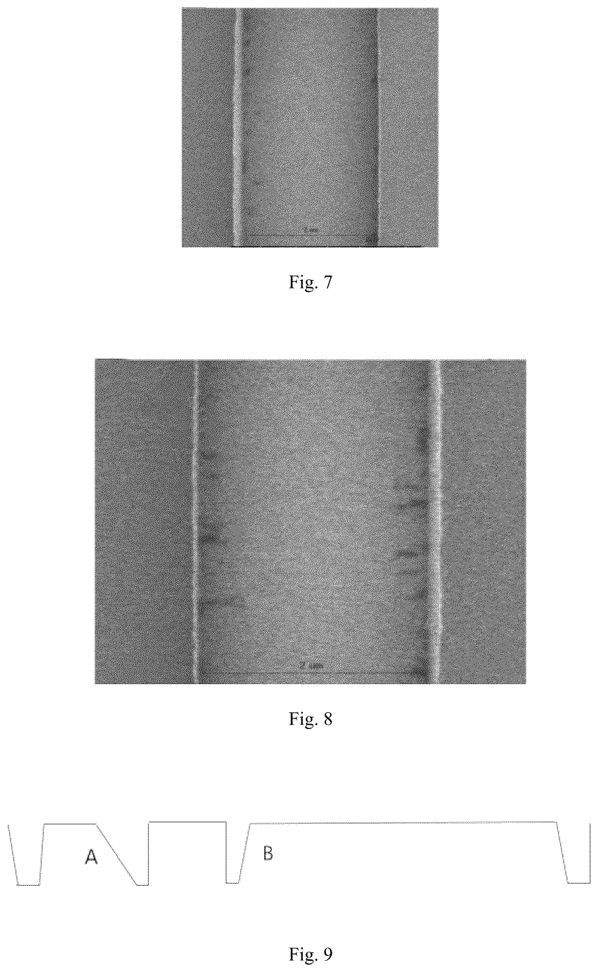

Through further extensive research, the inventors have found that the above-discussed overlay mark asymmetry, overlay mark damage or poor photoresist profiles usually occur to thick photoresist layers. An excessively thick photoresist layer may introduce asymmetry to a pattern by exposure, which may lead to measurement errors that can directly affect a scanner's compensation and correction for the layer. Thick photoresist layers are usually used as barrier layers in high-dose ion implantation processes. The aforementioned marks are large in size (typically 24 μm×24 μm) and therefore occupy large mask surface areas, making them more likely to introduce asymmetry to patterns formed in wafers. Reference is made to the electron microscopy images of FIGS. 6 to 8 and to the exemplary pattern cross-sectional view of FIG. 9. Inaccurate overlay error measurements will make an exposure machine impossible to effect timely compensation and correction, reducing the yield of products.

In view of this, it is a principal object of the present invention to provide a novel overlay mark additionally including an assist pattern in a current photoresist layer, which is provided at a corresponding location outside a previous-layer mark to isolate or block out the photoresist layer at the current-layer mark, thereby avoiding the current-layer mark from being affected by patterns surrounding the overlay mark. With this arrangement, when this IBO mark is used in thick photoresist applications, the current-layer mark is more resistant to deformation, increasing overall accuracy of overlay error measurement data so that the overall overlay error measurement data reflects a true photolithography overlay error.

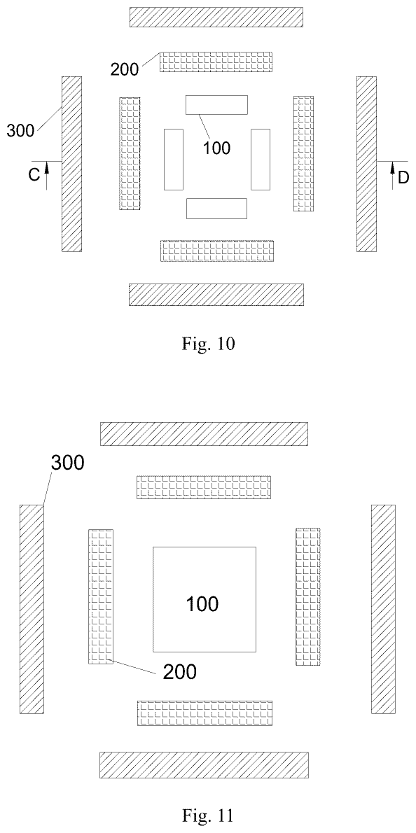

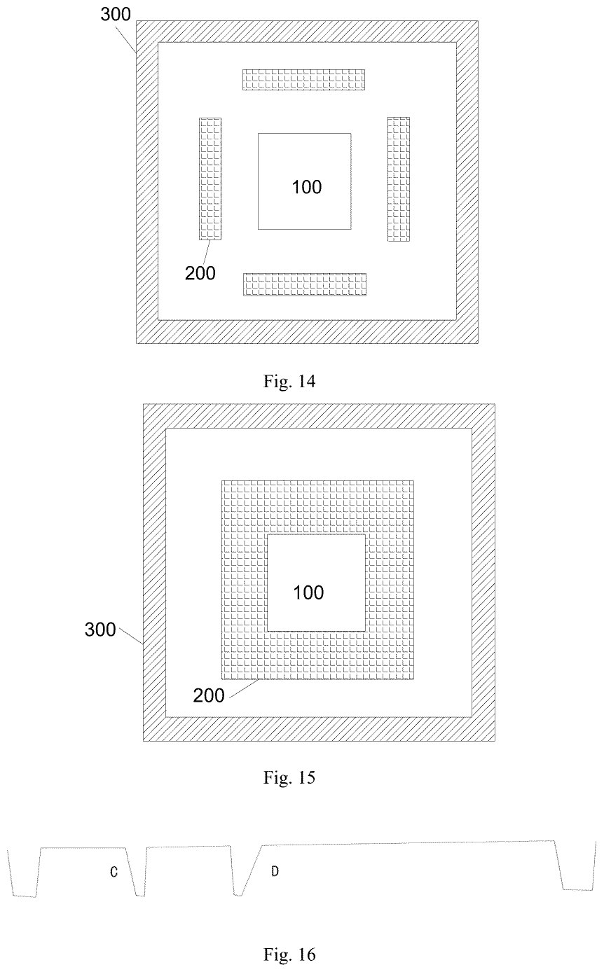

Particular reference is made to FIGS. 10 to 16, which are schematic diagrams of embodiments of the present invention. Also disclosed herein is a method of forming an overlay mark based on the same inventive concept. The overlay mark includes a main mark and at least one assist pattern 300. The main mark includes a previous-layer mark 200 and a current-layer mark 100. The current-layer mark 100 is arranged within a contour of the previous-layer mark 200, and the previous-layer mark 200 is arranged inside the assist pattern 300 or arranged on the internal side of the previous-layer mark 200. The method includes:
applying a photoresist layer to a substrate, in which the previous-layer mark 200 is formed; and
forming the current-layer mark 100 and the assist pattern 300 by exposing and developing the photoresist layer, and removing a portion of the photoresist layer at the assist pattern 300, isolating a portion of the photoresist layer at the current-layer mark 100.

As shown in FIGS. 10 to 15, when used for overlay error measurement in applications with thick photoresist, in particular with a thickness greater than 1 μm, the assist pattern 300 may be formed in the current photoresist layer at a corresponding location outside the previous-layer mark 200 to isolate or block out the photoresist layer at current-layer mark, thereby avoiding the current-layer mark from being affected by patterns surrounding the overlay mark. In this way, when this IBO overlay mark is used in thick photoresist applications, the current-layer mark is more resistant to deformation, increasing overall accuracy of overlay error measurement data so that overall overlay error measurement data reflects a true photolithography overlay error. FIG. 16 shows an exemplary photoresist profile obtainable by using the assist pattern 300 according to this disclosure.

Obviously, the previous-layer mark 200 may be directly formed by etching the substrate, or in a dielectric layer that has been formed on the substrate, without limiting the present invention in any sense. The previous layer may also be a hard mask (HM) or photoresist layer. With the assist pattern 300, optional compensation or balancing may be performed to reduce the presence of large blocks of photoresist around the mark. This can balance photoresist shrinkage and curing around the overlay mark, allowing the overlay mark to have an improved profile.

For example, the photoresist layer may be made of any viscous, photosensitive, correction-resistant polymer materials commonly used in semiconductor chip packaging or printed circuit fabrication, such as polyimide (PI), benzocyclobutene (BCB), poly(p-phenylene-2,6-benzobisoxazole) (PBO).

For example, the overlay mark may be an imaging-based overlay (IBO) mark.

In one embodiment, comprising a plurality of assist patterns 300 with each comprising a bar-like structure, the plurality of bar-like structures surround the previous-layer mark 200. For example, in accordance with the shape of the previous-layer mark 200, four bar-like structures may be provided.

As shown in FIG. 10, each of the previous-layer mark 200 and the current-layer mark 100 may be a rectangular mark consisting of four bar-like structures. Accordingly, one bar-like structure may be arranged external and parallel to each bar-like structure of the previous-layer mark 200, wherein this single bar-like structure serves as the assist pattern 300. As shown in FIG. 11, the previous-layer mark 200 may be a rectangular mark consisting of four bar-like structures, and the current-layer mark 100 may be a rectangular structure. Likewise, one bar-like structure may be arranged external and parallel to each bar-like structure of the previous-layer mark 200, wherein this single bar-like structure serves as the assist patterns 300.

Obviously, a suitable number of bar-like structures arranged into an appropriate pattern may be provided in accordance with the presence of photoresist around the previous-layer mark 200. For example, at least two bar-like structures may be provided as secondary marks 300 arranged external and parallel to each bar-like structure of the previous-layer mark 200. Alternatively, one bar-like structure may be provided external and parallel to one bar-like structure of the previous-layer mark 200, and at least two bar-like structures may be provided external and parallel to another bar-like structure of the previous-layer mark 200, and this arrangement of the bar-like structures serves as assist patterns 300.

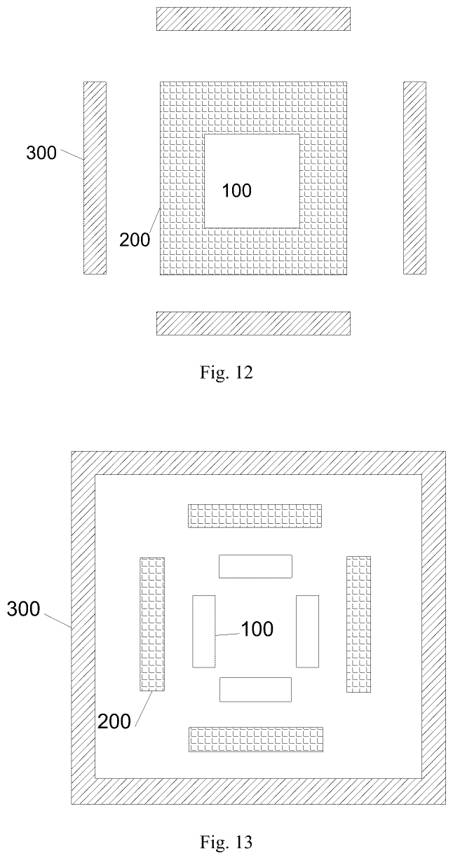

As shown in FIG. 12, each of the previous-layer mark 200 and the current-layer mark 100 may be a rectangular structure, and one bar-like structure may be provided parallel to each side of the previous-layer mark 200.

The assist pattern 300 may be spaced apart from the previous-layer mark 200 at a distance of 2-5 μm. In case of the bar-like structure being provided as assist pattern 300, the bar-like structure may have a length of 10-40 μm and a width of 1-5 μm.

In one embodiment, the assist pattern 300 may be a rectangular frame surrounding the previous-layer mark 200. As shown in FIGS. 13 to 15, when the previous-layer mark 200 and the current-layer mark 100 are of various structures, the assist pattern 300 of a rectangular frame surrounding the previous-layer mark 200 is formed. The assist pattern 300 may be spaced apart from the previous-layer mark 200 at a distance of 2-5 μm. In case of the assist pattern 300 being provided as a rectangular frame, its four sides may each have a length of 10-40 μm and a line width of 1-5 μm.

On the basis of the same inventive concept, there is also disclosed herein an overlay mark comprising:
a previous-layer mark 200 formed in a previous dielectric layer of a substrate, the previous-layer mark 200 comprising internal side and external side that is opposite to the external side;
a current-layer mark 100 formed in a current dielectric layer on the internal side of the previous-layer mark 200; and
at least one assist pattern 300 formed in the current dielectric layer at a corresponding location on the external side of the previous-layer mark 200, the assist pattern 300 spaced apart from the previous-layer mark 200 at a predetermined distance.

As shown in FIGS. 10 to 15, when used for overlay error measurement in applications with thick photoresist, in particular that material of the current dielectric layer is photoresist and a thickness of the photoresist is greater than 1 μm, a set of assist patterns 300 may be formed in the current photoresist layer outside a corresponding location of the previous-layer mark 200 to isolate or block out the photoresist layer at the current-layer mark, thereby avoiding the current-layer mark from being affected by patterns surrounding the overlay mark. In this way, when this IBO overlay mark is used in thick photoresist applications, the current-layer mark of the overlay mark is more resistant to deformation, increasing overall accuracy of overlay error measurement data so that the overall overlay error measurement data reflects a true photolithography overlay error. FIG. 16 shows an exemplary photoresist profile obtainable by using the assist pattern 300 according to this disclosure.

In one embodiment, comprising a plurality of assist patterns 300, each assist pattern comprises a bar-like structure, the plurality of bar-like structures surround the previous-layer mark 200. For example, in accordance with the shape of the previous-layer mark 200, four bar-like structures may be arranged.

As shown in FIG. 10, each of the previous-layer mark 200 and the current-layer mark 100 may be a rectangular mark consisting of four bar-like structures. Accordingly, one bar-like structure may be arranged external and parallel to each bar-like structure of the previous-layer mark 200, wherein this one bar-like structure serves as the assist patterns 300. As shown in FIG. 11, the previous-layer mark 200 may be a rectangular mark consisting of four bar-like structures, and the current-layer mark 100 may itself be a rectangular structure. Likewise, one bar-like structure may be arranged external and parallel to each bar-like structure of the previous-layer mark 200, wherein this one bar-like structure serves as the assist patterns 300.

Obviously, a suitable number of bar-like structures arranged into an appropriate pattern may be provided in accordance with the presence of photoresist around the previous-layer mark 200. For example, at least two bar-like structures may be provided as assist patterns 300 external and parallel to each bar-like structure of the previous-layer mark 200. Alternatively, one bar-like structure may be provided external and parallel to one bar-like structure of the previous-layer mark 200, and at least two bar-like structures may be provided external and parallel to another bar-like structure of the previous-layer mark 200, and this arrangement of the bar-like structure serves as assist pattern 300.

As shown in FIG. 12, each of the previous-layer mark 200 and the current-layer mark 100 may itself be a rectangular structure, and one bar-like structure may be provided parallel to the each side of the previous-layer mark 200.

The assist pattern 300 may be spaced apart from the previous-layer mark 200 at a distance of 2-5 μm. In case of the bar-like structures being provided as assist patterns 300, the bar-like structure may have a length of 10-40 μm and a width of 1-5 μm.

In one embodiment, the assist pattern 300 may be a rectangular frame surrounding the previous-layer mark 200. As shown in FIGS. 13 to 15, when the previous-layer mark 200 and the current-layer mark 100 are of various structures, the assist pattern 300 is provided as a rectangular frame surrounding the previous-layer mark 200. The assist pattern 300 may be spaced apart from the previous-layer mark 200 at a distance of 2-5 μm. In case of the assist pattern 300 being provided as a rectangular frame, its four sides may each have a length of 10-40 μm and a line width of 1-5 μm.

On the basis of the same inventive concept, there is also disclosed herein an overlay error measurement method using the overlay mark as discussed above, which includes the steps of:
providing a substrate formed therein with the previous-layer mark 200 and applying a photoresist layer to the substrate;
forming the current-layer mark 100 and the assist pattern 300 by exposing and developing the photoresist layer, and removing a portion of the photoresist layer at the assist pattern 300 and at the current-layer mark 100; and
measuring a deviation between the previous-layer mark 200 and the current-layer mark 100.

In the overlay mark and methods of forming same of the present invention, the assist pattern may be formed in the current photoresist layer at a corresponding location outside the previous-layer mark to isolate or block out the photoresist layer at current-layer mark, thereby avoiding the current-layer mark from being affected by patterns surrounding the overlay mark. In this way, when this IBO overlay mark is used in thick photoresist applications, the current-layer mark of the overlay mark is more resistant to deformation, increasing overall accuracy of overlay error measurement data so that the overall overlay error measurement data reflects a true photolithography overlay error.

The description presented above is merely that of some preferred embodiments of the present invention and does not limit the scope thereof in any sense. Any and all changes and modifications made by those of ordinary skill in the art based on the above teachings fall within the scope as defined in the appended claims.

What is claimed is:

1. A method of forming an overlay mark, wherein the overlay mark comprises a main mark and at least one assist pattern, wherein the main mark includes a previous-layer mark and a current-layer mark, wherein the current-layer mark is arranged within a contour of the previous-layer mark, wherein the previous-layer mark is arranged on an internal side of the assist pattern, and wherein the method comprises:
applying a photoresist layer to a substrate with the previous-layer mark being formed therein; and
forming the current-layer mark and the assist pattern by exposing and developing the photoresist layer, and removing a portion of the photoresist layer at the assist pattern, thereby isolating the photoresist layer at the current-layer mark.

2. The method according to claim 1, wherein the overlay mark is an imaging-based overlay (IBO) mark.

3. The method according to claim 1, wherein the assist pattern is spaced apart from the previous-layer mark at a predetermined distance of 2-5 μm.

4. The method according to claim 1, wherein the assist pattern is a rectangular frame surrounding the previous-layer mark.

5. The method according to claim 1, wherein the overlay mark comprises a plurality of assist patterns, wherein each assist pattern comprises a bar-like structure, and wherein a plurality of bar-like structures surround the previous-layer mark.

6. The method according to claim 1, wherein the photoresist layer has a thickness greater than 1 μm.

7. The method according to claim 1, wherein the assist pattern has a length of 10-40 μm.

8. An overlay mark formed according to the method of claim 1, comprising:
a previous-layer mark arranged in a previous dielectric layer of a substrate, wherein the previous-layer mark comprise an internal side and an external side opposite to the internal side;
a current-layer mark formed in a current dielectric layer and is located on the internal side of the previous-layer mark; and
at least one assist pattern formed in the current dielectric layer at a corresponding location on the external side of the previous-layer mark, wherein the assist pattern is spaced apart from the previous-layer mark at a predetermined distance.

9. The overlay mark according to claim 8, wherein the overlay mark is an imaging-based overlay (IBO) mark.

10. The overlay mark according to claim 8, wherein the assist pattern is spaced apart from the previous-layer mark at a predetermined distance of 2-5 μm.

11. The overlay mark according to claim 8, wherein the assist pattern is a rectangular frame surrounding the previous-layer mark.

12. The overlay mark according to claim 8, comprising a plurality of assist patterns, wherein each assist pattern comprises a bar-like structure, and wherein a plurality of bar-like structures surround the previous-layer mark.

13. The overlay mark according to claim 8, wherein the assist pattern has a length of 10-40 μm

14. The overlay mark according to claim 8, wherein in case of the current dielectric layer being made of photoresist, a thickness of the photoresist is greater than 1 μm.

15. An overlay error measurement method that is used to measure an overlay error of the overlay mark of claim 8.
